(19) United States
(12) Patent Application Publication
(10) Pub. No.: US 2026/0051714 A1
(43) Pub. Date: Feb. 19, 2026

(54) INTEGRATED BEAM STEERING DEVICE WITH INTENSITY MODULATOR

(71) Applicant: ELECTRONICS AND TELECOMMUNICATIONS RESEARCH INSTITUTE, Daejeon (KR)

(72) Inventors: Oh Kee KWON, Daejeon (KR); Chul-Wook Lee, Daejeon (KR); Young Ahn Leem, Daejeon (KR); Youngsun Moon, Daejeon (KR); Taehyun Park, Daejeon (KR)

(21) Appl. No.: 19/289,725

(22) Filed: Aug. 4, 2025

(30) Foreign Application Priority Data
Aug. 14, 2024 (KR) 10-2024-0109184

(51) Int. Cl. H01S 5/026; H01S 5/042

(52) U.S. Cl. CPC H01S 5/0268; H01S 5/0265; H01S 5/04256

(57) ABSTRACT

Provided is an integrated beam steering device. The steering device includes a substrate, a core layer provided on the substrate, a clad layer on the core layer, a plurality of upper electrodes provided on the clad layer, and a lower electrode provided on a lower surface of the substrate. Here, the substrate includes a source region configured to generate laser beam, a distribution region configured to transmit the laser beam, an amplification region configured to amplify the laser beam, a phase modulation region configured to modulate the phase of the laser beam, and a first intensity modulation region configured to modulate the intensity of the laser beam.

### CROSS-REFERENCE TO RELATED APPLICATION

This U.S. non-provisional patent application claims priority under 35 U.S. C. § 119 of Korean Patent Application No. 10-2024-0109184, filed on Aug. 14, 2024, the entire contents of which are hereby incorporated by reference.

### BACKGROUND

The present disclosure herein relates to a beam steering device, and more particularly, to an integrated beam steering device with an intensity modulator.

Recently, in inter-satellite communication, a laser communication scheme utilizing light instead of a typical RF frequency band has been actively introduced for the demand for large-capacity communication and for the smaller size/lighter weight, and low-power operation of communication payloads. The laser communication uses an unlicensed band that does not require frequency use permission, and allows for smaller and lighter-weight satellite payloads due to a decrease in antenna size, and has an advantage of large-capacity transmission and high energy efficiency due to a sufficient bandwidth and high directivity. In the inter-satellite laser communication, in addition to an optical transceiver for generating and detecting optical signals, a beam steering technique is required, which enables the control of the direction of beam distributed from a transmitter in order to form an optical path with a receiver of another satellite after recognizing the position of a satellite and controlling the attitude thereof. The beam steering method is largely classified into a mechanical method and a non-mechanical method, wherein the mechanical method commonly utilizes a fast steering mirror (FSM) configuration mainly based on motor, piezoelectric, and MEMS technology, and the non-mechanical method reportedly uses various methods such as an optical lens system and metamaterials, and in recent years, interest has been focused on the form of an electronic beam steering device in which a phase array antenna (PAA) and a tunable laser diode (TLD) are coupled. Particularly, since a phase-modulator array (PMA) and an arrayed antenna constituting the PAA may be implemented in the form of an optical waveguide, and may be integrated with the TLD, and thus research on the implementation in the form of a single ship by reducing the size has been in the spotlight.

### SUMMARY

The present disclosure provides an integrated beam steering device with an intensity modulator, which is capable of increasing reliability and communication efficiency.

An embodiment of the inventive concept provides an integrated beam steering device. The steering device includes a substrate, a core layer provided on the substrate, a clad layer on the core layer, a plurality of upper electrodes provided on the clad layer, and a lower electrode provided on a lower surface of the substrate. Here, the substrate may include a source region configured to generate laser beam, a distribution region spaced apart from the source region, and configured to transmit the laser beam, an amplification region provided between the source region and the distribution region, and configured to amplify the laser beam, a phase modulation region provided between the amplification region and the distribution region, and configured to modulate the phase of the laser beam, and a first intensity modulation region provided between the amplification region and the source region, and configured to modulate the intensity of the laser beam.

In an embodiment, the substrate may further include a separation region between the first intensity modulation region and the amplification region.

In an embodiment, the core layer may include an active core layer provided in the source region, a first modulation core layer provided in the first intensity modulation region, and an amplification core layer provided in the amplification region.

In an embodiment, the integrated beam steering device may further include a plurality of resonant gratings provided within the clad layer on both sides of the active core layer.

In an embodiment, the core layer may further include a plurality of resonant waveguides provided on both sides of the active core layer.

In an embodiment, the substrate may further include a plurality of first air pockets provided within the source region, and provided on both sides of the active core layer.

In an embodiment, the substrate may further include a second air pocket provided within the phase modulation region, and longer than the first air pockets.

In an embodiment, the substrate may further include a second modulation region provided between the distribution region and the phase modulation region.

In an embodiment, the core layer may further include a second modulation core layer provided within the second intensity modulation region, and the substrate may further include a third air pocket provided within the second intensity modulation region, and longer than the first air pocket.

In an embodiment, the integrated beam steering device may further include a middle electrode provided within the substrate between the second modulation core layer and the lower electrode, and a via electrode connecting the middle electrode to the lower electrode.

In an embodiment of the inventive concept, an integrated beam steering device includes a laser diode configured to generate laser beam, an antenna array connected to the laser diode, and configured to transmit the laser beam, an amplifier array provided between the laser diode and the antenna array, and configured to amplify the laser beam, a phase modulator array provided between the amplifier array and the antenna array, and configured to modulate the phase of the laser beam, a beam splitter provided between the amplifier array and the laser diode to split the laser beam into the amplifier array, and a first intensity modulator provided between the beam splitter and the laser diode, and configured to modulate the intensity of the laser beam.

In an embodiment, the first intensity modulator may include an electroabsorption modulator or a Mach-Zehnder modulator.

In an embodiment, the integrated beam steering device may further include a second intensity modulator provided between the antenna array and the phase modulator array.

In an embodiment, the second intensity modulator may include a substrate, a modulation core layer on the substrate, a clad layer on the modulation core layer, an upper electrode on the clad layer, a lower electrode on a lower surface of the substrate, and a middle electrode provided within the substrate on the lower electrode.

In an embodiment, the second intensity modulator may further include a via electrode provided within the substrate and connecting the middle electrode to the lower electrode.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram showing an example of an integrated beam steering device according to an embodiment of the inventive concept;

FIG. 2 is a plan view showing an application example of the integrated beam steering device of FIG. 1;

FIG. 3 and FIG. 4 are cross-sectional views taken along line I-I′ of FIG. 2;

FIG. 5A is a plan view showing an example of a laser diode of FIG. 2;

FIG. 5B is a cross-sectional view taken along line II-II′ of FIG. 5A;

FIG. 6A is a plan view showing an example of the laser diode of FIG. 2;

FIG. 6B is a cross-sectional view taken along line III-III′ of FIG. 5A;

FIG. 7A is a plan view showing an example of a first intensity modulator of FIG. 2;

FIG. 7B is a cross-sectional view taken along line IV-IV′ of FIG. 7A;

FIG. 8A is a plan view showing an example of the first intensity modulator of FIG. 2;

FIG. 8B is a cross-sectional view taken along line IV-IV′ of FIG. 8A;

FIG. 9A is a plan view showing an example of an antenna array of FIG. 2;

FIG. 9B is a cross-sectional view taken along line VI-VI′ of FIG. 9A;

FIG. 10A is a plan view showing an example of the antenna array of FIG. 2;

FIG. 10B is a cross-sectional view taken along line VII-VII′ of FIG. 10A;

FIG. 11A is a plan view showing an example of the antenna array of FIG. 2;

FIG. 11B is a cross-sectional view taken along line VIII-VIII′ of FIG. 11A;

FIG. 12 is a plan view showing an application example of the integrated beam steering device of FIG. 1;

FIG. 13 is a plan view showing an application example of the integrated beam steering device of FIG. 1;

FIG. 14 is a block diagram showing an example of an integrated beam steering device according to an embodiment of the inventive concept;

FIG. 15 is a cross-sectional view showing an application example of the integrated beam steering device of FIG. 14; and

FIG. 16 is a cross-sectional view showing an application example of the integrated beam steering device of FIG. 14.

### DETAILED DESCRIPTION

In order to facilitate sufficient understanding of the configuration and effects of a technical idea of the present invention, preferred embodiments of the technical idea of the present invention will be described with reference to the accompanying drawings. However, the technical idea of the present invention is not limited to the embodiments set forth below, and may be embodied in various forms and modified in many alternate forms. Rather, the present embodiments are provided such that the disclosure of the technical idea of the present invention will be complete, and to fully convey the scope of the present invention to those skilled in the art to which the present invention pertains.

Like reference numerals refer to like elements throughout the specification. The embodiments described in the present specification will be described with reference to plan views, perspective views, and/or cross-sectional views, which are ideal illustrations of the technical idea of the present invention. In the drawings, the thickness of regions are exaggerated for an effective description of technical contents. Thus, the regions illustrated in the drawings have schematic properties, and the shapes of the regions illustrated in the drawings are intended to exemplify specific shapes of regions of a device and are not intended to limit the scope of the present invention. Although various terms are used in various embodiments of the present specification to describe various elements, these elements should not be limited by these terms. These terms are only used to distinguish one element from another. The embodiments described and illustrated herein also include complementary embodiments thereof.

The terms used herein are for the purpose of describing embodiments and are not intended to be limiting of the present invention. In the present specification, singular forms include plural forms unless the context clearly indicates otherwise. As used herein, the terms ‘comprises’and/or ‘comprising’ are intended to be inclusive of the stated elements, and do not exclude the possibility of the presence or the addition of one or more other elements.

Hereinafter, the preferred embodiments of the technical idea of the present invention will be described with reference to the accompanying drawings to describe the present invention in detail.

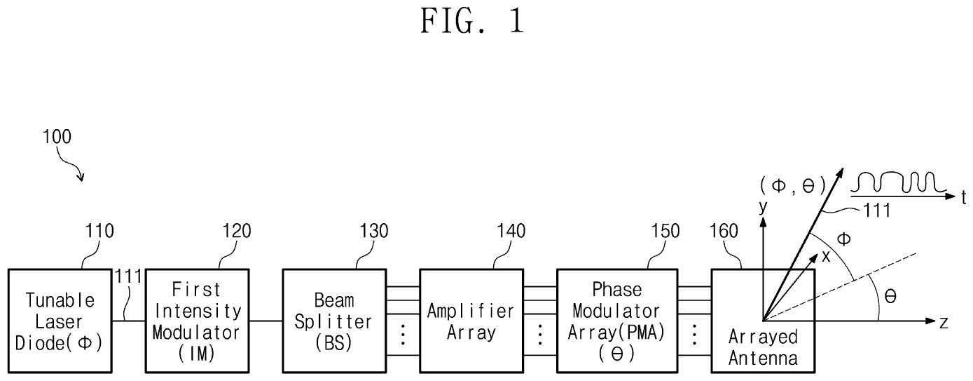

FIG. 1 shows an example of an integrated beam steering device 100 according to the inventive concept.

Referring to FIG. 1, the integrated beam steering device 100 of the inventive concept may include an integrated beam steering device with intensity modulator. According to an embodiment, the integrated beam steering device 100 of the inventive concept may include a laser diode 110, a first intensity modulator 120, a beam splitter 130, an amplifier array 140, a phase modulator array 150, and an antenna array 160.

The laser diode 110 may generate laser beam 111. The laser beam 111 may include a continuous wave laser beam. The laser diode 110 may include a tunable laser diode. The first intensity modulator 120 may be connected to the laser diode 110. The first intensity modulator 120 may modulate the intensity of the laser beam 111. For example, the first intensity modulator 120 may modulate the laser beam 111 into a pulse laser beam. That is, the first intensity modulator 120 may generate pulses of the laser beam 111. The beam splitter 130 may be connected to the first intensity modulator 120. The beam splitter 130 may split the laser beam 111 and provide the split laser beam 111 to the amplifier array 140. The amplifier array 140 may amplify the laser beam 111. The phase modulator array 150 may be connected to the amplifier array 140. The phase modulator array 150 may modulate the phase of the laser beam 111. The antenna array 160 may be connected to the phase modulator array 150. The antenna array 160 may wirelessly transmit the laser beam 111. The laser beam 111 may be wirelessly distributed with an azimuthal angle (θ) and a polar angle (ϕ) from the antenna array 160.

Therefore, the integrated beam steering device 100 of the inventive concept is capable of increasing reliability and communication efficiency by using the first intensity modulator 120 to generate pulses of the laser beam 111.

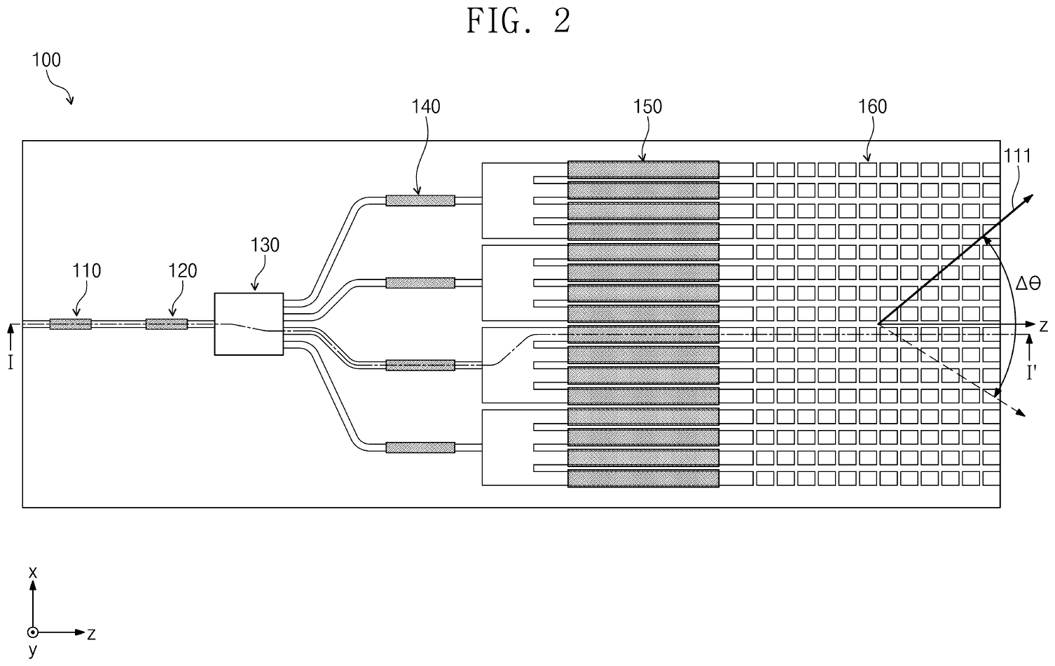

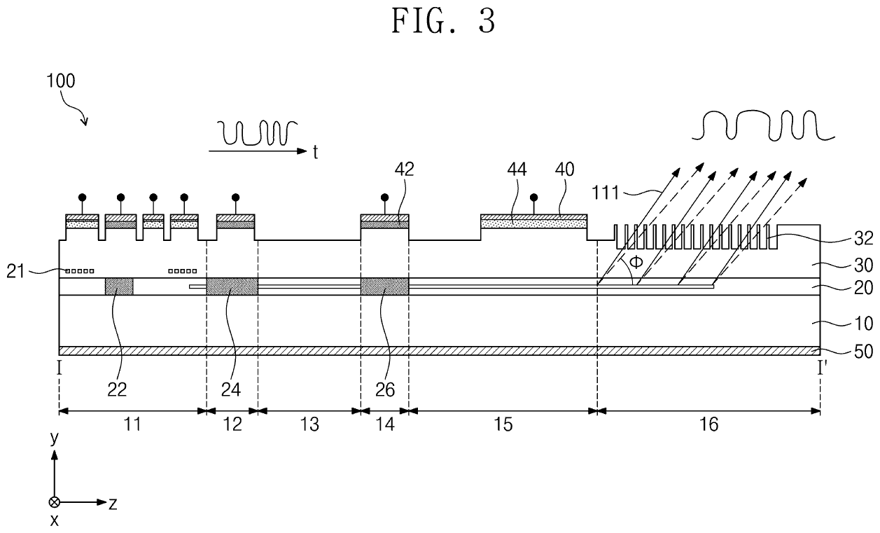

FIG. 2 shows an application example of the integrated beam steering device 100 of FIG. 1. FIG. 3 shows a view taken along line I-I′ of FIG. 2.

Referring to FIG. 2 to FIG. 3, the integrated beam steering device 100 of the inventive concept may include a substrate 10, a waveguide core layer 20, a clad layer 30, upper electrodes 40, and a lower electrode 50.

The substrate 10 may include n-type InP. On the other hand, the substrate 10 may include silicon-on-insulation (SOI), quartz, glass, silicon oxide, or silicon wafer, but the embodiment of the inventive concept is not limited thereto. According to an embodiment, the substrate 10 may include a source region 11, a first intensity modulation region 12, a separation region 13, an amplification region 14, a phase modulation region 15, and a distribution region 16.

The waveguide core layer 20 may be provided on the substrate 10. The waveguide core layer 20 may have a refractive index higher than that of the substrate 10. The waveguide core layer 20 may include intrinsic InP. On the other hand, the waveguide core layer 20 may include InGaAs, but the embodiment of the inventive concept is not limited thereto. The waveguide core layer 20 may be a passive waveguide layer. The waveguide core layer 20 of the passive waveguide layer may be provided on the substrate 10 of the separation region 13, the phase modulation region 15, and a distribution region 16. According to an example, the waveguide core layer 20 may further include an active core layer 22, a first modulation core layer 24, and an amplification core layer 26.

The active core layer 22 may be provided on the substrate 10 of the source region 11. The active core layer 22 may be a gain region. The active core layer 22 may obtain gains of the laser beam 111. For example, the active core layer 22 may include InGaAsP.

The first modulation core layer 24 may be provided on the substrate 10 of the first intensity modulation region 12. The first modulation core layer 24 may modulate the intensity of the laser beam 111. For example, the first modulation core layer 24 may include InGaAsP.

The amplification core layer 26 may be provided on the substrate 10 of the amplification region 14. The amplification core layer 26 may amplify the laser beam 111. For example, the amplification core layer 26 may include InGaAsP.

The clad layer 30 may be provided on the waveguide core layer 20. The clad layer 30 may have a refractive index lower than that of the waveguide core layer 20. The clad layer 30 may have a refractive index lower than that of the waveguide core layer 20. For example, the clad layer 30 may include p-type InP.

Resonant gratings 21 may be provided within the clad layer 30. The resonant gratings 21 may be provided within the clad layer 30 on both sides of the active core layer 22. The resonant gratings 21 may resonate the laser beam 111. The resonant gratings 21 may include impurities within the clad layer 30. For example, the clad layer 30 may include InGaAsP.

The clad layer 30 may have an etched grating 32. The etched grating 32 may be provided on the clad layer 30 of the distribution region 16. The etched grating 32 may have a comb shape from a vertical viewpoint. The etched grating 32 may transmit the laser beam 111. The polar angle (ϕ) of the laser beam 111 may be determined by diffraction conditions of the etched grating 32.

The upper electrodes 40 may be provided on the clad layer 30. The upper electrodes 40 may be provided on the source region 11, the first intensity modulation region 12, the amplification region 14, and the phase modulation region 15. The number of upper electrodes 40 of the source region 11 may be approximately 3. The upper electrodes 40 may be provided on the active core layer 22, and on both sides of the active core layer 22. The upper electrode 40 on the active core layer 22 may obtain the gains of the laser beam 111. The upper electrodes 40 on both sides of the active core layer 22 may tune the oscillation wavelength of the laser beam 111.

An ohmic contact layer 42 may be provided between the clad layer 30 of the active core layer 22, the first modulation core layer 24, and the amplification core layer 26 and the upper electrodes 40. The ohmic contact layer 42 may reduce contact resistance between the upper electrodes 40 and the clad layer 30. Through the ohmic contact layer 42 and the clad layer 30, the upper electrodes 40 may provide a current to the active core layer 22 to oscillate the laser beam 111, modulate the intensity of the laser beam 111, and modulate the phase thereof. For example, the ohmic contact layer 42 may include a work function metal layer of tungsten (W), tantalum (Ta), indium (In), cobalt (Co), or a rare earth. Although not illustrated, a dielectric layer may be provided between the clad layer 30 of the active core layer 22, the first modulation core layer 24, and the amplification core layer 26 and the upper electrodes 40. The dielectric layer may insulate the clad layer 30 and the upper electrodes 40. The upper electrodes 40 may heat the clad layer 30, the active core layer 22, the first modulation core layer 24, and the amplification core layer 26 to oscillate the laser beam 111, modulate the intensity of the laser beam 111, and modulate the phase thereof.

An interlayer insulation layer 44 may be provided between the clad layer 30 of the resonance gratings 21 and the phase modulation region 15 and the upper electrodes 40. The interlayer insulation layer 44 may include silicon oxide or silicon nitride. The upper electrodes 40 may heat the waveguide core layer 20 to resonate the laser beam 111 and change the phase thereof.

The lower electrode 50 may be provided on a lower surface of the substrate 10. The lower electrode 50 may be provided from the source region 11 of the substrate 10 to the distribution region 16. A bias voltage may be provided between the upper electrodes 40 and the lower electrode 50 to oscillate and amplify the laser beam 111, and change the intensity or phase of the laser beam 111.

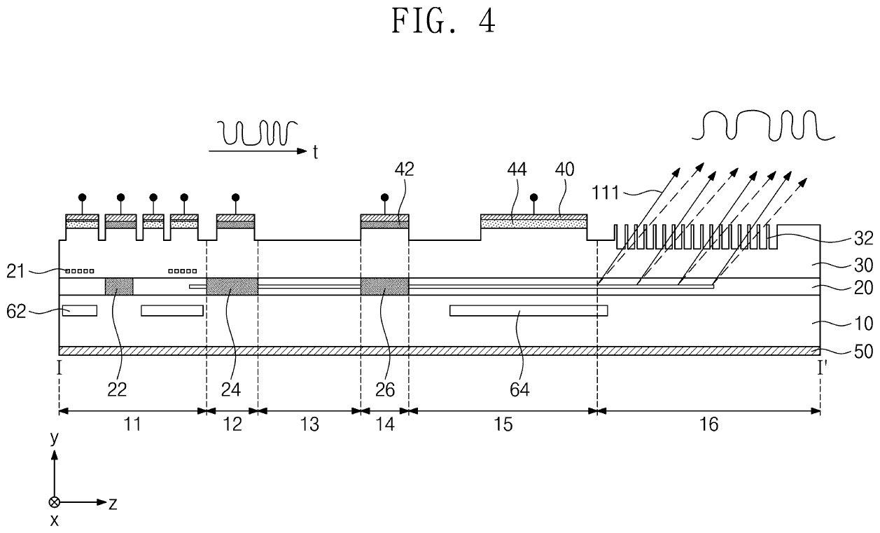

FIG. 4 shows an application example of the integrated beam steering device 100 of FIG. 1.

Referring to FIG. 4, a substrate 10 of the integrated beam steering device 100 may include first air pockets 62 and a second air pocket 64. The first air pockets 62 may be provided within a source region 11 of the substrate 10, and the second air pocket 64 may be provided within a phase modulation region 15. The first air pockets 62 and the second air pocket 64 may reduce or prevent heating of upper electrodes 40 from being conducted to the substrate 10, thereby increasing resonance efficiency and phase modulation efficiency of laser beam 111. Alternatively, the first air pockets 62 and the second air pocket 64 may decrease the dielectric constant of the substrate 10.

The substrate 10, a waveguide core layer 20, a clad layer 30, the upper electrodes 40, and a lower electrode 50 may be configured in the same manner as in FIG. 3.

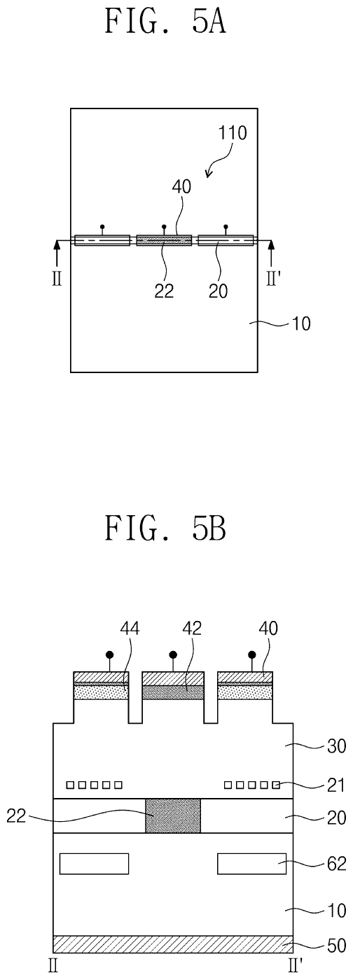

FIG. 5A shows an example of the laser diode 110 of FIG. 2. FIG. 5B shows a view taken along line II-II′ of FIG. 5A.

Referring to FIG. 5A and FIG. 5B, the laser diode 110 may have first air pockets 62. The first air pockets 62 may be provided within a substrate 10 on both sides of an active core layer 22. The first air pockets 62 may reduce or prevent heating of upper electrodes 40 from being conducted to the substrate 10. Alternatively, the first air pockets 62 may decrease the dielectric constant of the substrate 10 to increase oscillation efficiency of laser beam 111.

A waveguide core layer 20, a clad layer 30, the upper electrodes 40, and a lower electrode 50 may be configured in the same manner as in FIG. 3 and FIG. 4.

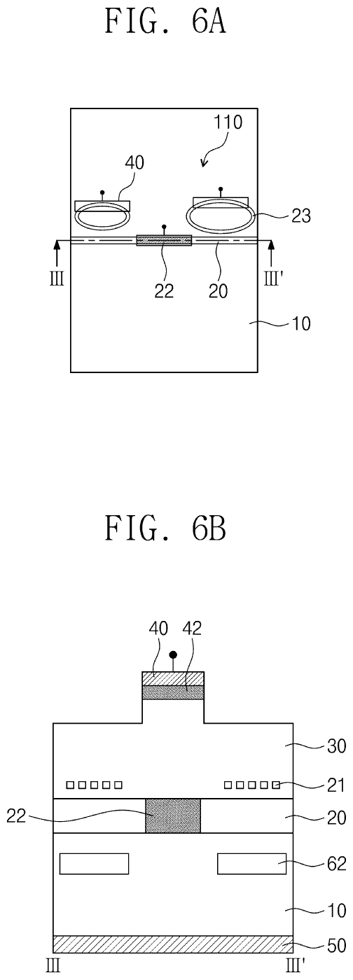

FIG. 6A shows an example of the laser diode 110 of FIG. 2. FIG. 6B shows a view taken along line III-III′ of FIG. 6A.

Referring to FIG. 6A and FIG. 6B, the laser diode 110 may have a plurality of resonant waveguides 23. The resonant waveguides 23 may be provided on both sides of an active core layer 22. The resonant waveguides 23 may include a ring waveguide. Each of the resonant waveguides 23 may have an elliptical or circular shape from a planar viewpoint. The resonant waveguides 23 may be different in length. The resonant waveguides 23 may resonate laser beam 111. Upper electrodes 40 may be provided on the resonant waveguides 23. The upper electrodes 40 may heat the resonant waveguides 23 to change the oscillation wavelength of the laser beam 111. In addition, gratings 21 may be provided on a waveguide core layer 20 on both sides of the active core layer 22 adjacent to the resonant waveguides 23. The gratings 21 may be provided within a clad layer 30. The gratings 21 may resonate the laser beam 111.

A substrate 10, the waveguide core layer 20, the clad layer 30, the upper electrodes 40, and a lower electrode 50 may be configured in the same manner as in FIG. 3 and FIG. 4.

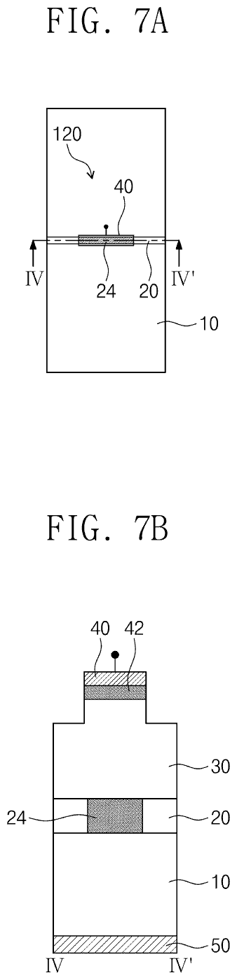

FIG. 7A shows an example of the first intensity modulator 120 of FIG. 2. FIG. 7B shows a view taken along line IV-IV′ of FIG. 7A.

Referring to FIG. 7A and FIG. 7B, the first intensity modulator 120 may include an electroabsorption modulator (EAM). The first intensity modulator 120 may electrically control the absorption rate of a modulation core layer 24 of a first intensity modulation region 12 to modulate the intensity of laser beam 111 into a pulse form.

A substrate 10, a waveguide core layer 20, a clad layer 30, upper electrodes 40, and a lower electrode 50 may be configured in the same manner as in FIG. 3 and FIG. 4.

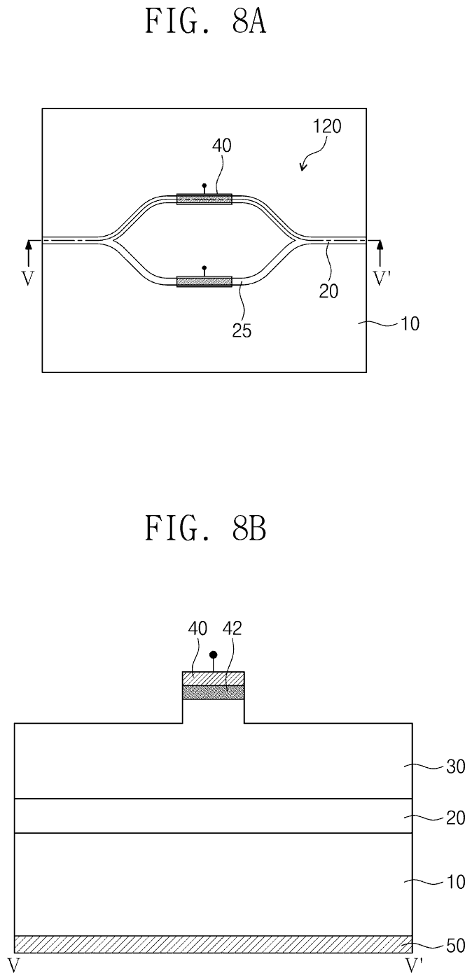

FIG. 8A shows an example of the first intensity modulator 120 of FIG. 2. FIG. 8B shows a view taken along line V-V′ of FIG. 8A.

Referring to FIG. 8A and FIG. 8B, the first intensity modulator 120 may include a Mach-Zehnder modulator. According to an embodiment, the first intensity modulator 120 may include a plurality of branch core layers 25 and upper electrodes 40. The branch core layers 25 may include Y-branch waveguides facing each other from a planar viewpoint. The branch core layers 25 may be branched and then coupled again. The branched branch core layers 25 may transmit laser beam 111. The branched branch core layers 25 may include a passive waveguide layer. The upper electrodes 40 may be provided on the branch core layers 25. The upper electrodes 40 may control the phase of the laser beam 111. The coupled branch core layers 25 may interfere with the laser beam 111. If the phase difference of the laser beam 111 is 0 or 2π, the laser beam 111 may be constructively interfered. If the phase difference of the laser beam 111 is π, the laser beam 111 may destructively interfered and disappeared. Therefore, the laser beam 111 may have pulses by the constructive interference and the destructive interference.

A substrate 10, a waveguide core layer 20, a clad layer 30, the upper electrodes 40, and a lower electrode 50 may be configured in the same manner as in FIG. 3 and FIG. 4.

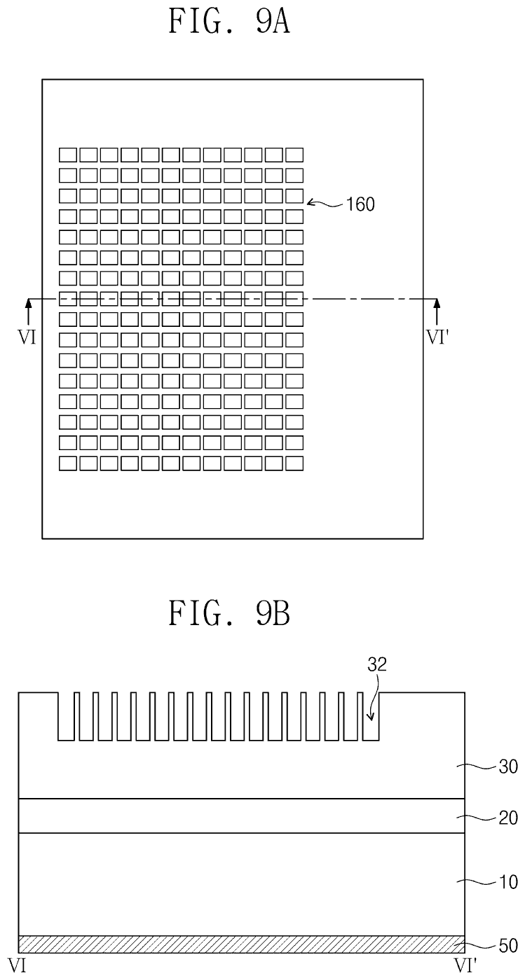

FIG. 9A shows an example of the antenna array 160 of FIG. 2. FIG. 9B shows a view taken along line VI-VI′ of FIG. 9A.

Referring to FIG. 9A and FIG. 9B, a clad layer 30 of the antenna array 160 may include an etched grating 32. The etched grating 32 may be formed on an upper surface of the clad layer 30.

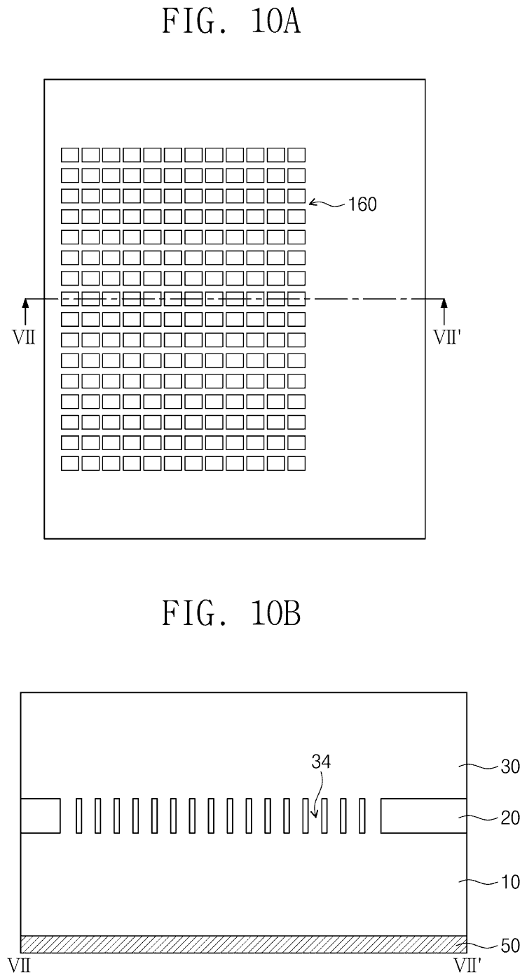

FIG. 10A shows an example of the antenna array 160 of FIG. 2. FIG. 10B shows a view taken along line VII-VII′ of FIG. 10A.

Referring to FIG. 10A and FIG. 10B, a waveguide core layer 20 may have an etched passive core layer 34.

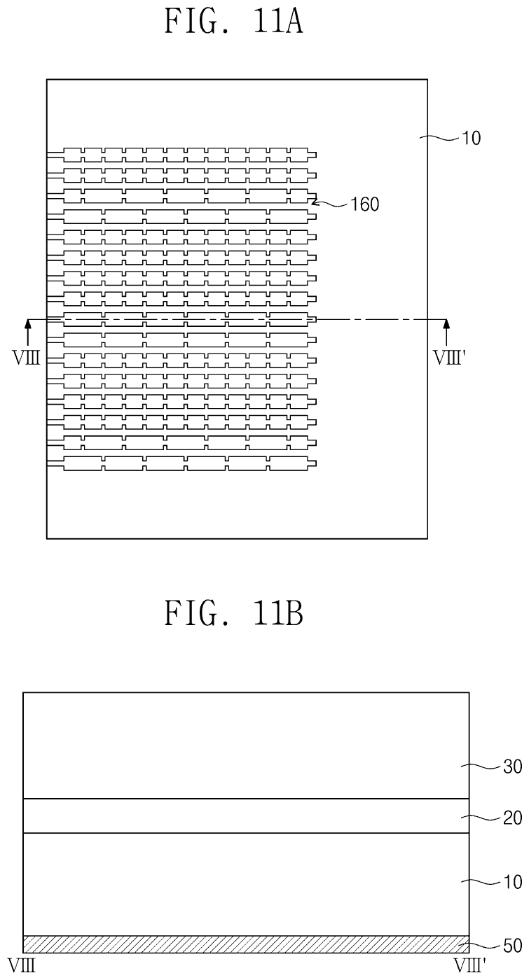

FIG. 11A shows an example of the antenna array 160 of FIG. 2. FIG. 11B shows a view taken along line VIII-VIII′ of FIG. 11A.

Referring to FIG. 11A and FIG. 11B, a waveguide core layer 20 of the antenna array 160 may have a changed width or a patterned width. The waveguide core layer 20 may have a width that changes in a direction perpendicular to the extension direction thereof.

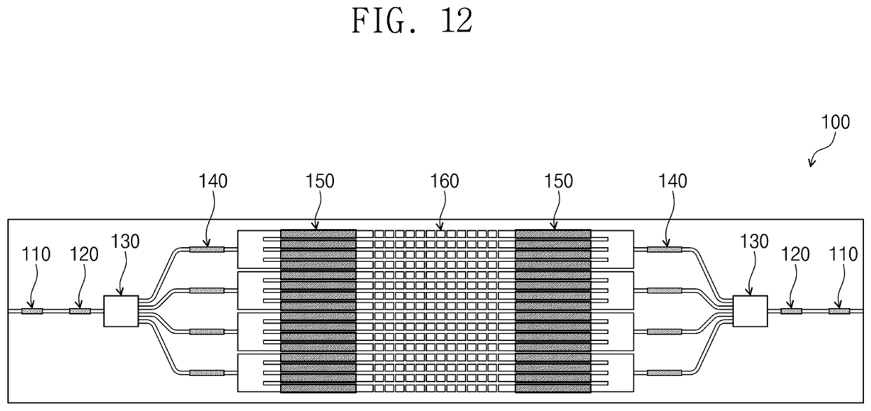

FIG. 12 shows an application example of the integrated beam steering device 100 of FIG. 1.

Referring to FIG. 12, a plurality of laser diodes 110, first intensity modulators 120, beam splitters 130, an amplifier array 140, and a phase modulator array 150 of the integrated beam steering device 100 of the inventive concept may be provided on both sides of an antenna array 160.

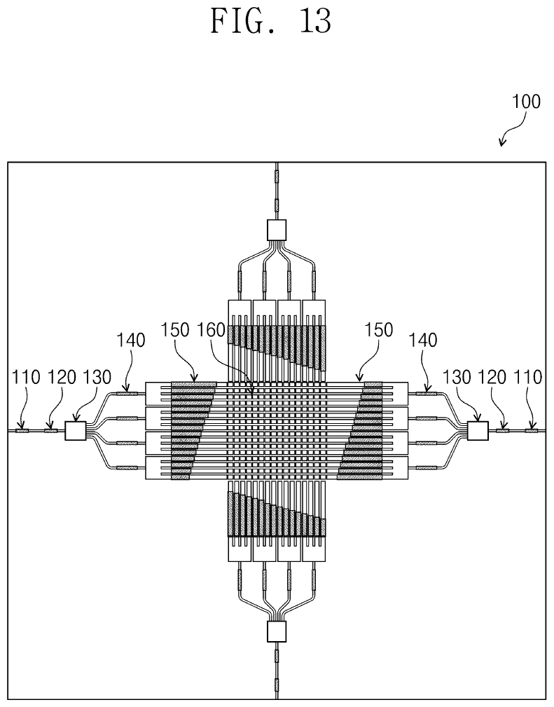

FIG. 13 shows an application example of the integrated beam steering device 100 of FIG. 1.

Referring to FIG. 13, laser diodes 110, first intensity modulators 120, beam splitters 130, an amplifier array 140, and a phase modulator array 150 of the integrated beam steering device 100 of the inventive concept may be provided in all directions of horizontal and vertical directions of an antenna array 160.

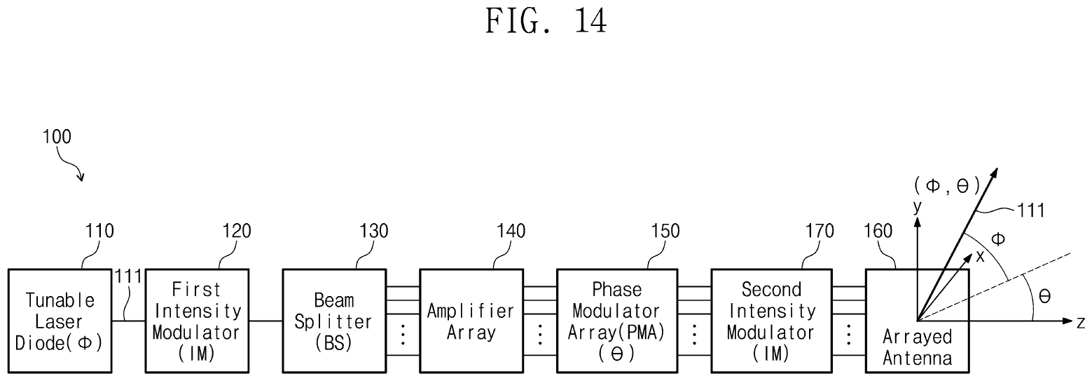

FIG. 14 shows an example of the integrated beam steering device 100 according to the inventive concept.

Referring to FIG. 14, the integrated beam steering device 100 of the inventive concept may further include a second intensity modulator 170.

The second intensity modulator 170 may be provided between a phase modulator array 150 and an antenna array 160. The second intensity modulator 170 may additionally modulate the intensity of laser beam 111, the phase of which has been modulated in the phase modulator array 150. The second intensity modulator 170 may modulate the laser beam 111 into pulses identical to those of the first intensity modulator 120.

A laser diode 110, the first intensity modulator 120, a beam splitter 130, an amplifier array 140, the phase modulator array 150, and the antenna array 160 may be configured in the same manner as in FIG. 1.

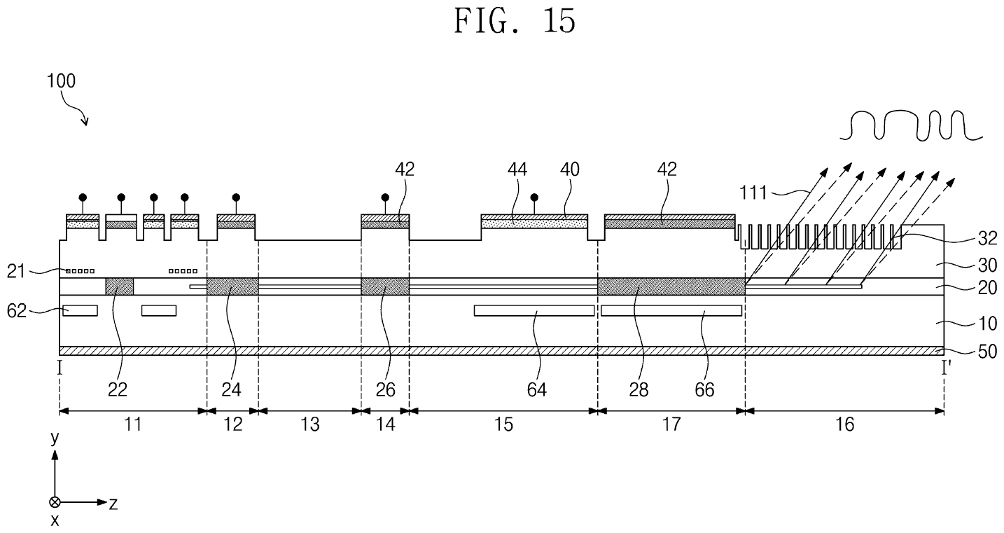

FIG. 15 shows an application example of the integrated beam steering device 100 of FIG. 14.

Referring to FIG. 15, a second intensity modulator 170 of the integrated beam steering device 100 of the inventive concept may further include a second modulation core layer 28 and a third air pocket 66 of a second intensity modulation region 17.

The second modulation core layer 28 may be provided within a waveguide core layer 20 of the second intensity modulation region 17. The second modulation core layer 28 may use a current between a lower electrode 50 and an upper electrode 40 to modulate the intensity of laser beam 111. On the other hand, the second modulation core layer 28 may use heating of the upper electrode 40 to modulate the intensity of the laser beam 111.

The third air pocket 66 may be provided within a substrate 10 between the second modulation core layer 28 and the lower electrode 50. The third air pocket 66 may reduce the effective refractive index of the substrate 10 to reduce the intensity modulation efficiency of the laser beam 111. On the other hand, the third air pocket 66 may reduce the consumption of heating of the upper electrode 40 to increase the intensity modulation efficiency.

The substrate 10, the waveguide core layer 20, a clad layer 30, the upper electrode 40, and the lower electrode 50 may be configured in the same manner as in FIGS. 3 and 4.

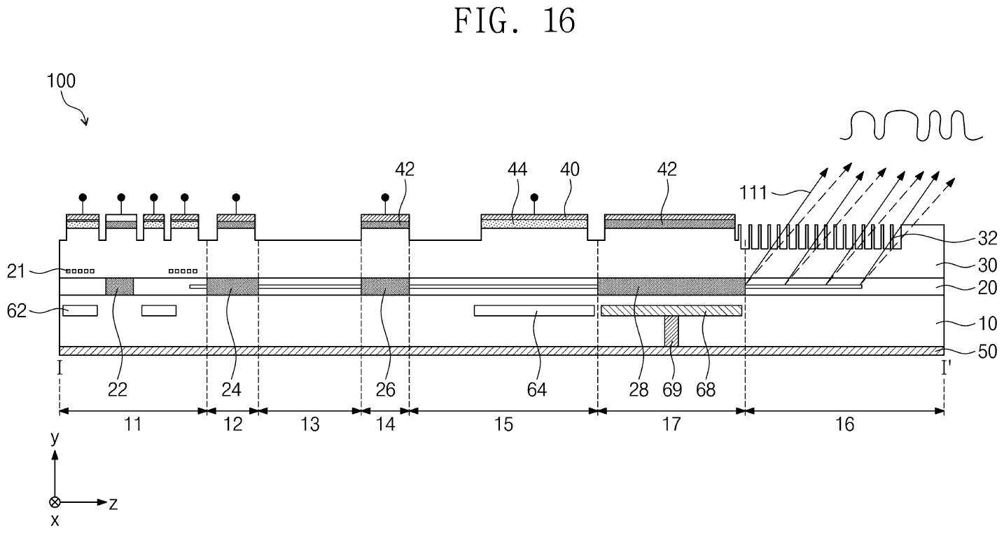

FIG. 16 shows an application example of the integrated beam steering device 100 of FIG. 14.

Referring to FIG. 16, a second intensity modulator 170 of the integrated beam steering device 100 of the inventive concept may include an electroabsorption modulator. According to an embodiment, the second intensity modulator 170 may further include a middle electrode 68. The middle electrode 68 may be provided within a substrate 10 of a second intensity modulation region 17. The middle electrode 68 may be provided adjacent to a second air pocket 64. The middle electrode 68 may be connected to a lower electrode 50 by a via electrode 69. The middle electrode 68 may reduce an effective distance between the lower electrode 50 and an upper electrode 40 to increase intensity modulation efficiency and reduce power consumption.

The substrate 10, a waveguide core layer 20, a clad layer 30, the upper electrode 40, and the lower electrode 50 may be configured in the same manner as in FIGS. 3 and 4.

An integrated beam steering device according to an embodiment of the inventive concept is capable of increasing reliability and communication efficiency by using an intensity modulator to generate pulses of laser beam.

Although the embodiments of the present invention have been described with reference to the accompanying drawings, those skilled in the art will understand that the present invention can be implemented in other specific forms without changing the technical spirit or essential features thereof. Therefore, the embodiments described above should be understood as illustrative in all respects and not restrictive.

What is claimed is:

1. An integrated beam steering device comprising:
a substrate;
a core layer provided on the substrate;
a clad layer on the core layer;
a plurality of upper electrodes provided on the clad layer; and
a lower electrode provided on a lower surface of the substrate,
wherein the substrate includes:
a source region configured to generate laser beam;
a distribution region spaced apart from the source region, and configured to transmit the laser beam;
an amplification region provided between the source region and the distribution region, and configured to amplify the laser beam;
a phase modulation region provided between the amplification region and the distribution region, and configured to modulate the phase of the laser beam; and
a first intensity modulation region provided between the amplification region and the source region, and configured to modulate the intensity of the laser beam.

2. The integrated beam steering device of claim 1, wherein the substrate further comprises a separation region between the first intensity modulation region and the amplification region.

3. The integrated beam steering device of claim 1, wherein the core layer comprises:
an active core layer provided in the source region;
a first modulation core layer provided in the first intensity modulation region; and
an amplification core layer provided in the amplification region.

4. The integrated beam steering device of claim 3, further comprising a plurality of resonant gratings provided within the clad layer on both sides of the active core layer.

5. The integrated beam steering device of claim 3, wherein the core layer further comprises a plurality of resonant waveguides provided on both sides of the active core layer.

6. The integrated beam steering device of claim 2, wherein the substrate further comprises a plurality of first air pockets provided within the source region, and provided on both sides of the active core layer.

7. The integrated beam steering device of claim 6, wherein the substrate further comprises a second air pocket provided within the phase modulation region, and longer than the first air pockets.

8. The integrated beam steering device of claim 6, wherein the substrate further comprises a second modulation region provided between the distribution region and the phase modulation region.

9. The integrated beam steering device of claim 8, wherein:
the core layer further comprises a second modulation core layer provided within the second intensity modulation region; and
the substrate further comprises a third air pocket provided within the second intensity modulation region, and longer than the first air pocket.

10. The integrated beam steering device of claim 9, further comprising:
a middle electrode provided within the substrate between the second modulation core layer and the lower electrode; and
a via electrode connecting the middle electrode to the lower electrode.

11. An integrated beam steering device comprising:
a laser diode configured to generate laser beam;
an antenna array connected to the laser diode, and configured to transmit the laser beam;
an amplifier array provided between the laser diode and the antenna array, and configured to amplify the laser beam;
a phase modulator array provided between the amplifier array and the antenna array, and configured to modulate the phase of the laser beam;
a beam splitter provided between the amplifier array and the laser diode to split the laser beam into the amplifier array; and
a first intensity modulator provided between the beam splitter and the laser diode, and configured to modulate the intensity of the laser beam.

12. The integrated beam steering device of claim 11, wherein the first intensity modulator comprises an electroabsorption modulator or a Mach-Zehnder modulator.

13. The integrated beam steering device of claim 11, further comprising a second intensity modulator provided between the antenna array and the phase modulator array.

14. The integrated beam steering device of claim 11, wherein the second intensity modulator comprises:
a substrate;
a modulation core layer on the substrate;
a clad layer on the modulation core layer;
an upper electrode on the clad layer;
a lower electrode on a lower surface of the substrate; and
a middle electrode provided within the substrate on the lower electrode.

15. The integrated beam steering device of claim 12, wherein the second intensity modulator further comprises a via electrode provided within the substrate and connecting the middle electrode to the lower electrode.
